(19) United States
(12) Patent Application Publication
(10) Pub. No.: US 2026/0020261 A1
(43) Pub. Date: Jan. 15, 2026

(54) SEMICONDUCTOR DEVICE WITH RESISTANCE MODIFICATION DOPED REGION AND METHOD FOR FABRICATING THE SAME

(71) Applicant: NANYA TECHNOLOGY CORPORATION, NEW TAIPEI CITY (TW)

(72) Inventor: CHIN-LING HUANG, NEW TAIPEI CITY (TW)

(21) Appl. No.: 18/772,499

(22) Filed: Jul. 15, 2024

(51) Int. Cl. H01L 29/94; H01L 23/62

(52) U.S. Cl. CPC H10D 1/66; H01L 23/62

(57) ABSTRACT

The present application discloses a semiconductor device and a method for fabricating the semiconductor device. The semiconductor device includes a substrate; a well region positioned within the substrate; an isolation structure positioned in the well region; a fuse medium positioned over the well region; a gate electrode positioned over the fuse medium; a fuse doped region positioned under the fuse medium and within the well region; a source/drain region positioned adjacent to the fuse doped region; and a resistance modification doped region partially overlapping the fuse doped region. The fuse doped region and the resistance modification doped region have a first conductive type and the well region has a second conductive type different from the first conductive type.

### TECHNICAL FIELD

The present disclosure relates to a semiconductor device and a method for fabricating the semiconductor device, and more particularly, to a semiconductor device with a resistance modification doped region and a method for fabricating the semiconductor device with the resistance modification doped region.

### DISCUSSION OF THE BACKGROUND

With the rapid growth of the electronics industry, the development of integrated circuits (ICs) has achieved high performance and miniaturization. Technological advances in IC materials and design have produced generations of ICs where each generation has smaller and more complex circuits than the previous generation.

A Dynamic Random Access Memory (DRAM) device is a type of random access memory that stores each bit of data in a separate capacitor within an integrated circuit. Typically, a DRAM is arranged in a square array of one capacitor and transistor per cell. A vertical transistor has been developed for the 4F² DRAM cell, in which F represents the photolithographic minimum feature width or critical dimension (CD). However, recently, DRAM manufacturers are facing significant challenges as technology nodes improve.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate; a well region positioned within the substrate; an isolation structure positioned in the well region; a fuse medium positioned over the well region; a gate electrode positioned over the fuse medium; a fuse doped region positioned under the fuse medium and within the well region; a source/drain region positioned adjacent to the fuse doped region; and a resistance modification doped region partially overlapping the fuse doped region. The fuse doped region and the resistance modification doped region have a first conductive type and the well region has a second conductive type different from the first conductive type.

Another aspect of the present disclosure provides a semiconductor device including a substrate; a well region positioned within the substrate; an isolation structure positioned in the well region; a fuse medium positioned over the well region; a gate electrode positioned over the fuse medium; a fuse doped region positioned under the fuse medium and within the well region; a source/drain region positioned adjacent to the fuse doped region; and a plurality of impurities positioned within the well region and under the gate electrode. The fuse doped region has a first conductive type and the well region has a second conductive type different from the first conductive type.

Another aspect of the present disclosure provides a method for fabricating a semiconductor device including providing substrate; forming a well region in the substrate; forming an isolation structure in the well region; forming a resistance modification doped region within the well region; forming a fuse doped region within the well region; and forming a gate electrode over the fuse doped region. The fuse doped region and the resistance modification doped region have a first conductive type and the well region has a second conductive type different from the first conductive type.

Due to the design of the semiconductor device of the present disclosure, the resistance modification doped region may make a fuse to be an ohmic type fuse when a fuse medium is blown out under an operation current under 4 mA (e.g., a current under 1.2 mA). The resistance of an ohmic type fuse is positively proportional to a temperature and has a resistance with a lower deviation. As a result, the misjudgment of the determination of a read operation and/or a write operation can be reduced.

The foregoing has outlined rather broadly the features and technical advantages of the present disclosure in order that the detailed description of the disclosure that follows may be better understood. Additional features and advantages of the disclosure will be described hereinafter and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRA WINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

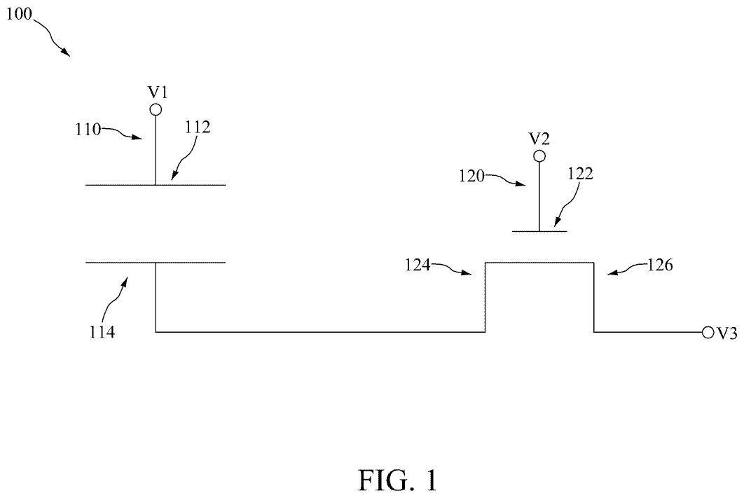

FIG. 1 is a diagram of a circuit in accordance with some embodiments of the present disclosure;

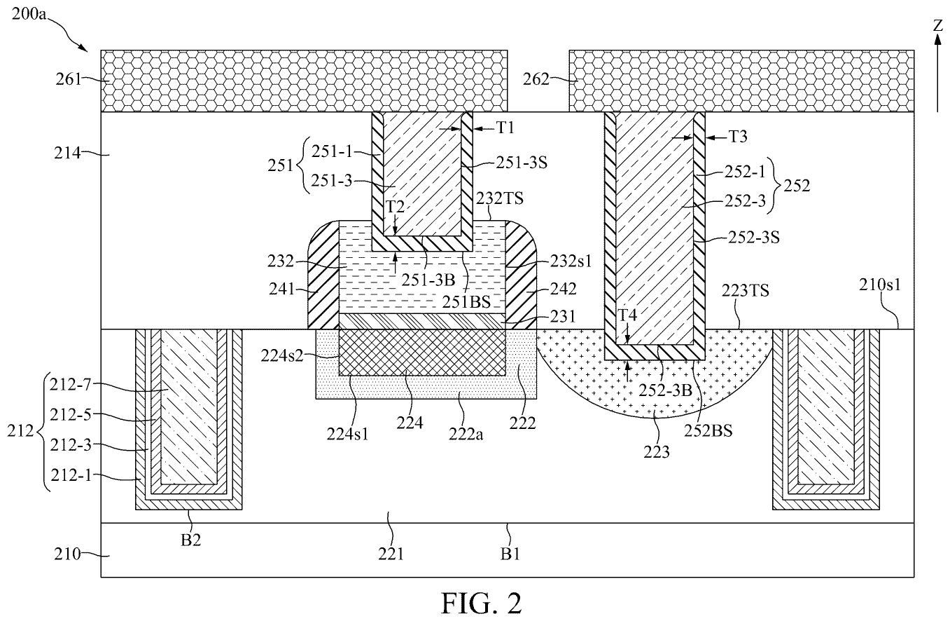

FIGS. 2 to 6 are cross-sections of semiconductor devices in accordance with some embodiments of the present disclosure;

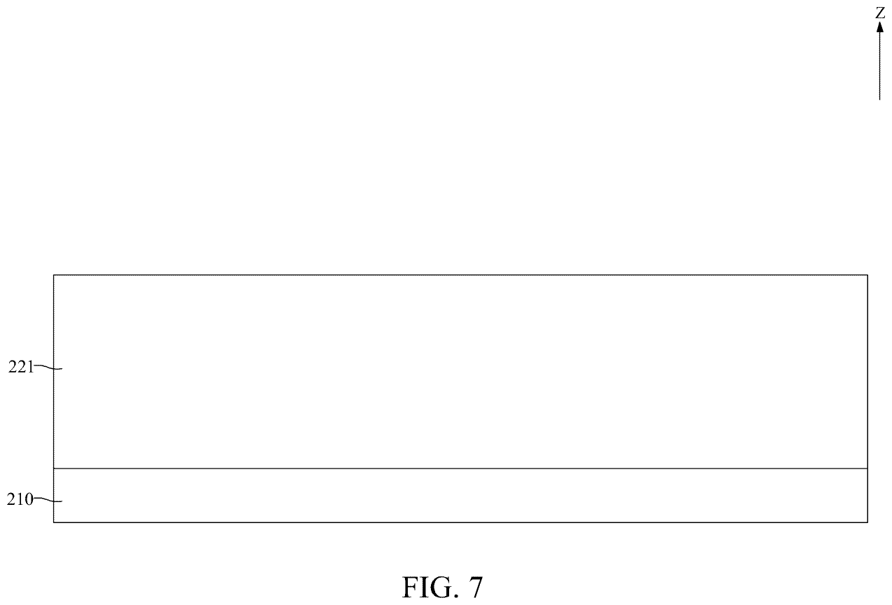

FIGS. 7 to 22 illustrates one or more stages of an exemplary method for manufacturing a semiconductor device according to some embodiments of the present disclosure;

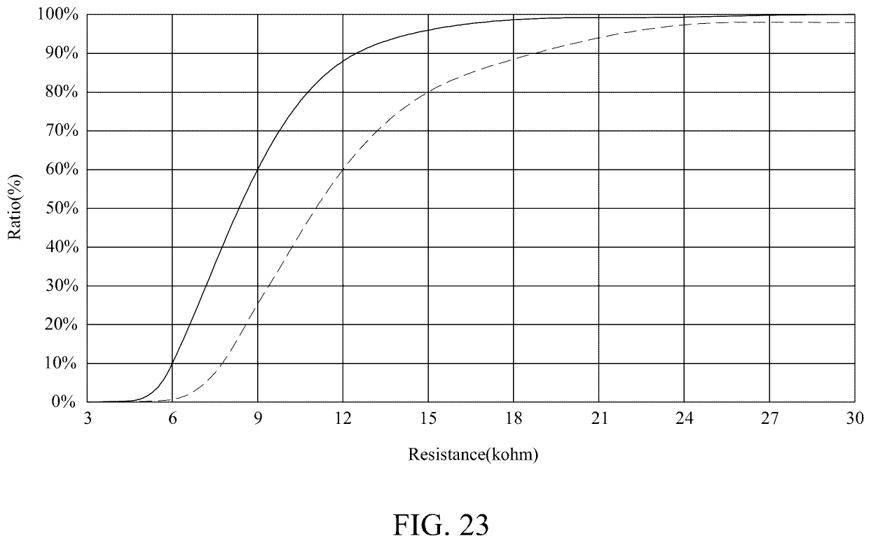

FIG. 23 illustrates a diagram showing a relation between a temperature and a resistance of a hopping type fuse;

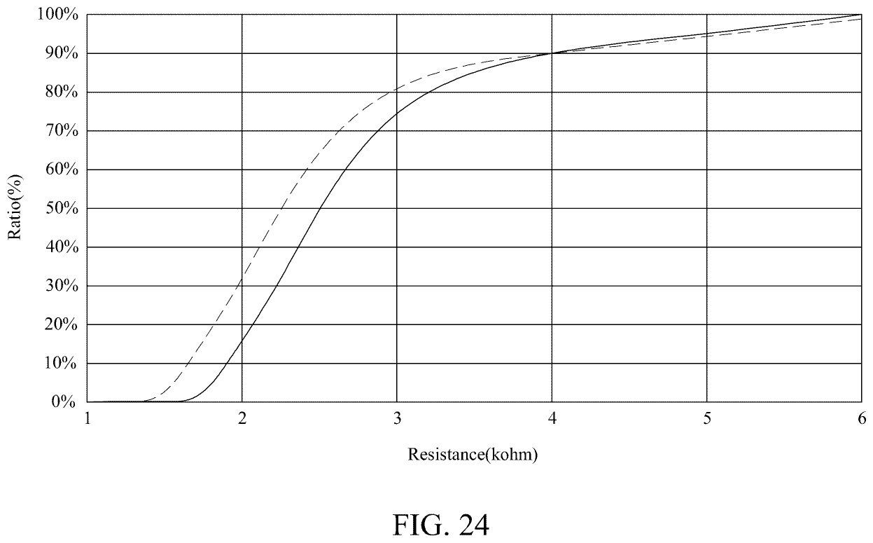

FIG. 24 illustrates a diagram showing a relation between a temperature and a resistance of an ohmic type fuse;

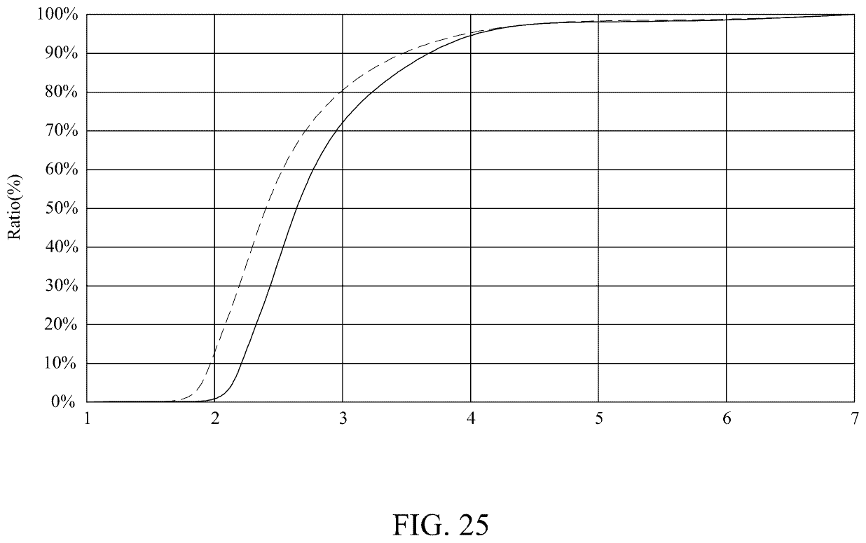

FIG. 25 illustrates a diagram showing a relation between a temperature and a resistance of an ohmic type fuse; and

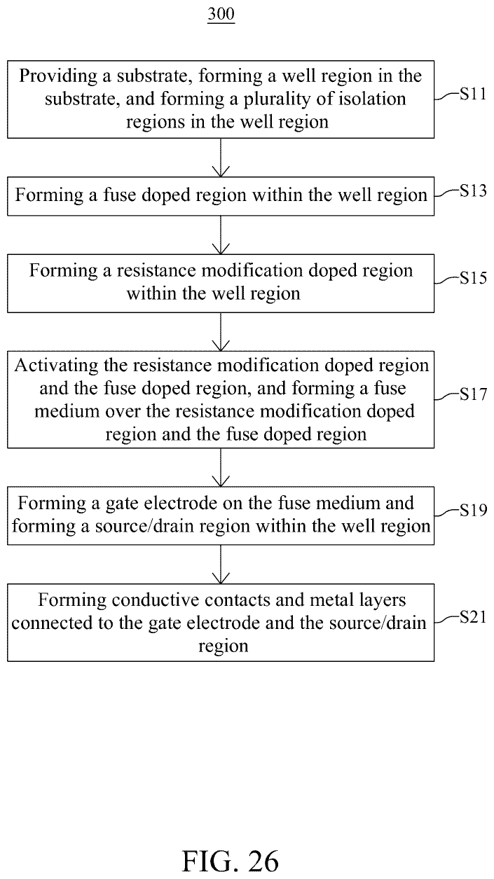

FIG. 26 is a flowchart illustrating a method of manufacturing a semiconductor device in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

FIG. 1 is a diagram of a circuit 100 in accordance with some embodiments of the present disclosure. In some embodiments, the circuit 100 may include a fuse 110 and a transistor 120. The circuit 100 may be included in a memory device, such as a dynamic random access memory (DRAM) device, a one-time programming (OTP) memory device, a static random access memory (SRAM) device, or other suitable memory devices.

The fuse 110 may include a terminal 112 and a terminal 114. The terminal 112 may be electrically connected to a supply voltage V1. The terminal 114 may be electrically connected to the transistor 120.

The transistor 120 may be electrically connected to the fuse 110. The transistor 120 may include a terminal 122, a terminal 124, and a terminal 126. The terminal 122 may be electrically connected to a supply voltage V2. The terminal 124 may be electrically connected to the terminal 114. The terminal 126 may be electrically connected to a supply voltage V3.

In some embodiments, during a read operation, a word line (e.g., the terminal 122) may be asserted, turning on the transistor 120. The enabled transistor 120 allows the voltage across the fuse 110 to be read by a detection amplifier through a bit line (not shown). During a write operation, the data to be written may be provided on the bit line when the word line is asserted.

FIG. 2 is a cross-section of a semiconductor device 200a, in accordance with some embodiments of the present disclosure. In some embodiments, the semiconductor device 200a may be applicable to the circuit 100. For example, the semiconductor device 200a may include a structure that functions as a fuse, such as the fuse 110 as shown in FIG. 1.

With reference to FIG. 2, in some embodiments, the semiconductor device 200a may include a substrate 210. The substrate 210 may be a semiconductor substrate, such as a bulk semiconductor, a semiconductor-on-insulator (SOI) substrate, or the like. The substrate 210 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may include a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 210 may have a multilayer structure, or the substrate 210 may include a multilayer compound semiconductor structure. The substrate 210 may have a surface 210s1.

With reference to FIG. 2, in some embodiments, the semiconductor device 200a may include a well region 221. The well region 221 may be disposed within the substrate 210. In some embodiments, the substrate 210 may have a first conductive type, and the well region 221 may have a second conductive type opposite to the first conductive type. For example, the substrate 210 is n-type, and the well region 221 is p-type.

With reference to FIG. 2, in some embodiments, the semiconductor device 200a may include a plurality of isolation structures 212 disposed in the well region 221. In some embodiments, the well region 221 may be not penetrated through by the isolation structure 212. The bottom surface B2 of the isolation structure 212 may be higher than the bottom surface B1 of the well region 221.

In some embodiments, the isolation structure 212 may include a first liner 212-1, a second liner 212-3 disposed over the first liner 212-1, a third liner 212-5 disposed over the second liner 212-3, and a trench filling layer 212-7 disposed over the third liner 212-5. In some embodiments, the trench filling layer 212-7 may be surrounded by the third liner 212-5, the third liner 212-5 may be surrounded by the second liner 212-3, and the second liner 212-3 may be separated from the well region 221 by the first liner 212-1. In other words, the second liner 212-3 may be surrounded by the first liner 212-1.

In some embodiments, the top surfaces of the first liner 212-1, the second liner 212-3, the third liner 212-5 and the trench filling layer 212-7 may be substantially coplanar.

In some embodiments, the first liner 212-1, the second liner 212-3 and the third liner 212-5 of the isolation structure 212 may be formed of different materials. For example, the first liner 212-1 may be formed of silicon oxide, the second liner 212-3 may be formed of nitride, and the third liner 212-5 may be formed of silicon oxynitride. In some embodiments, a first etching selectivity may exist between the second liner 212-3 and the trench filling layer 212-7, and a second etching selectivity may exist between the third liner 212-5 and the trench filling layer 212-7.

With reference to FIG. 2, in some embodiments, the semiconductor device 200a may include a fuse doped region 222. The fuse doped region 222 may be disposed within the well region 221 of the substrate 210. The fuse doped region 222 may have the first conductive type different from the conductive type of the well region 221. In some embodiments, the fuse doped region 222 may be n-type.

With reference to FIG. 2, in some embodiments, the semiconductor device 200a may include a source/drain (S/D) region 223. The S/D region 223 may be disposed within the well region 221. The S/D region 223 may be adjacent to the fuse doped region 222. The S/D region 223 may be in contact with the fuse doped region 222. The S/D region 223 may partially overlap the fuse doped region 222. The S/D region 223 may have the first conductive type (i.e., n-type).

With reference to FIG. 2, in some embodiments, the semiconductor device 200a may include a resistance modification doped region 224. The resistance modification doped region 224 may be disposed within the well region 221. The resistance modification doped region 224 may overlap the fuse doped region 222. The resistance modification doped region 224 may have the first conductive type (i.e., n-type). In some embodiments, the resistance modification doped region 224 may have dopants including nitrogen and/or nitrogen derivatives. In some embodiments, the dopant concentration of the resistance modification doped region 224 may range from about 10¹⁵ atoms/cm³ to about 10¹⁶ atoms/cm³.

In some embodiments, the resistance modification doped region 224 may be configured to make the semiconductor device 200a as an ohmic type fuse after the semiconductor device 200a is blown out, which will be described in detail later. In some embodiments, the resistance modification doped region 224 may be configured to modify the relation between the resistance of a fuse (e.g., the semiconductor device 200a) and a temperature under a specific operation current. For example, the resistance modification doped region 224 may make the resistance of a fuse (e.g., the semiconductor device 200a) positively proportional to a temperature under an operation current ranging from about 0.4 mA to about 1.2 mA, such as 0.4 mA, 0.5 mA, 0.6 mA, 0.7 mA, 0.8 mA, 0.9 mA, 1 mA, 1.1 mA, or 1.2 mA. The operation current may be configured to blow a fuse medium (e.g., fuse medium 231) out, and therefore a resistance of a fuse medium may be changed.

With reference to FIG. 2, in some embodiments, the semiconductor device 200a may include a fuse medium 231. The fuse medium 231 may be disposed on the surface 210s1 of the substrate 210. In some embodiments, the fuse medium 231 may vertically overlap the fuse doped region 222. In some embodiments, the fuse medium 231 may vertically overlap with the resistance modification doped region 224. The fuse medium 231 may have a single layer or a multi-layer structure. In some embodiments, the fuse medium 231 may include dielectric material such as silicon oxide, silicon nitride, silicon oxynitride, other dielectric materials, or a combination thereof. In some embodiments, the fuse medium 231 is a multi-layer structure that includes an interfacial layer and a high-k (dielectric constant greater than 4) dielectric layer. The interfacial layer can include dielectric material such as silicon oxide, silicon nitride, silicon oxynitride, other dielectric materials, or a combination thereof. The high-k dielectric layer can include high-k dielectric material such as HfO₂. HfSiO, HfSiON, HfTaO, HfTiO, HfZrO, other suitable high-k dielectric materials, or a combination thereof. In some embodiments, the high-k dielectric material can further be selected from metal oxides, metal nitrides, metal silicates, transition metal-oxides, transition metal-nitrides, transition-metal silicates, metal oxynitrides, metal aluminates, and combinations thereof.

With reference to FIG. 2, in some embodiments, the semiconductor device 200a may include a gate electrode 232. The gate electrode 232 may be disposed on the fuse medium 231. The gate electrode 232 may include polysilicon, silicon-germanium, and/or at least one metallic material including elements and compounds such as Mo, Cu, W, Ti, Ta, TiN, TaN, TaN, NiSi, CoSi, or other suitable conductive materials. In some embodiments, the gate electrode 232 may include a work function metal layer that provides a metal gate with an n-type-metal work function or p-type-metal work function. The p-type-metal work function materials may include materials such as ruthenium, palladium, platinum, cobalt, nickel, conductive metal oxide, or other suitable materials. The n-type-metal work function materials may include materials such as hafnium zirconium, titanium, tantalum, aluminum, metal carbides (e.g., hafnium carbide, zirconium carbide, titanium carbide, and aluminum carbide), aluminides, or other suitable materials.

With reference to FIG. 2, in some embodiments, the semiconductor device 200a may include a spacer 241 and a spacer 242. The spacer 241 may be disposed on a lateral surface 232s1 of the gate electrode 232. The spacer 242 may be disposed on the lateral surface 232s1 of the gate electrode 232 and opposite to the spacer 241 with the gate electrode 232 interposed therebetween. The spacer 241 and spacer 242 may include a single layer structure or a multilayer structure. The spacer 241 and spacer 242 may include dielectric material such as silicon oxide, silicon nitride, silicon oxynitride, other dielectric materials, or a combination thereof. In some embodiments, the spacer 241 (or spacer 242) may vertically overlap the fuse doped region 222. In some embodiments, the spacer 241 (or spacer 242) may be free from vertically overlapping the resistance modification doped region 224.

With reference to FIG. 2, in some embodiments, a dielectric layer 214 may be formed on the well region 221, the S/D region 223, and the isolation structure 212. The gate electrode 232, the spacer 241 and spacer 242 may be covered by the dielectric layer 214. In some embodiments, the dielectric layer 214 may be formed of, for example, silicon oxide, undoped silicate glass, fluorosilicate glass, borophosphosilicate glass, a spin-on low-k dielectric layer, a chemical vapor deposition low-k dielectric layer, or a combination thereof. The term “low-k” as used throughout the present application denotes a dielectric material that has a dielectric constant of less than silicon dioxide. In some embodiments, the dielectric layer 214 may include a self-planarizing material such as a spin-on glass or a spin-on low-k dielectric material such as SiLK™. The use of a self-planarizing dielectric material may avoid the need to perform a subsequent planarizing step. In some embodiments, the dielectric layer 214 may be formed by a deposition process including, for example, chemical vapor deposition, plasma enhanced chemical vapor deposition, evaporation, or spin-on coating.

A planarization process, such as chemical mechanical polishing, may be performed to remove excess material and provide a substantially flat surface for subsequent processing steps.

With reference to FIG. 2, in some embodiments, the semiconductor device 200a may include a conductive contact 251 and a conductive contact 252. The conductive contact 251 may be disposed on the gate electrode 232. The conductive contact 251 may be electrically connected to the gate electrode 232. The conductive contact 252 may be disposed on the S/D region 223. The conductive contact 252 may be electrically connected to the S/D region 223.

In some embodiments, the conductive contact 251 may extend to the gate electrode 232. The bottom surface 251BS of the conductive contact 251 may be higher than the top surface 232TS of the gate electrode 232. In some embodiments, the conductive contact 252 may extend to the S/D region 223. The bottom surface 252BS of the conductive contact 252 may be higher than the top surface 223TS of the S/D region 223.

In some embodiments, the conductive contact 251 may include a barrier portion 251-1 and a bulk portion 251-3. In some embodiments, the barrier portion 251-1 may have a U-shaped cross-sectional profile in a cross-sectional perspective. The barrier portion 251-1 may penetrate the dielectric layer 214 and extend into the gate electrode 232. The barrier portion 251-1 may be surrounded by the dielectric layer 214 and the gate electrode 232. The bulk portion 251-3 may be disposed over the barrier portion 251-1 and surrounded by the barrier portion 251-1.

In some embodiments, the barrier portion 251-1 may include titanium, titanium nitride, or a combination thereof, and the bulk portion 251-3 may include tungsten. In some embodiments, the bulk portion 251-3 may be separated from the dielectric layer 214 and the gate electrode 232 by the barrier portion 251-1.

It should be noted that the barrier portion 251-1 may have a first thickness T1 on the sidewalls 251-3S of the bulk portion 251-3, and the barrier portion 251-1 may have a second thickness T2 under the bottom surface 251-3B of the bulk portion 251-3. In some embodiments, the barrier portion 251-1 may be formed by an anisotropic deposition process so that the first thickness T1 is less than the second thickness T2. In some embodiments, the anisotropic deposition process for forming the barrier portion 251-1 may include a physical vapor deposition process.

In some embodiments, the conductive contact 252 may include a barrier portion 252-1 and a bulk portion 252-3. In some embodiments, the barrier portion 252-1 may have a U-shaped cross-sectional profile in a cross-sectional perspective. The barrier portion 252-1 may penetrate the dielectric layer 214 and extend into the S/D region 223. The barrier portion 252-1 may be surrounded by the dielectric layer 214 and the S/D region 223. The bulk portion 252-3 may be disposed over the barrier portion 252-1 and surrounded by the barrier portion 252-1.

In some embodiments, the barrier portion 252-1 may include titanium, titanium nitride, or a combination thereof, and the bulk portion 252-3 may include tungsten. In some embodiments, the bulk portion 252-3 may be separated from the dielectric layer 214 and the S/D region 223 by the barrier portion 252-1.

It should be noted that the barrier portion 252-1 may have a third thickness T3 on the sidewalls 252-3S of the bulk portion 252-3, and the barrier portion 252-1 may have a fourth thickness T4 under the bottom surface 252-3B of the bulk portion 252-3. In some embodiments, the barrier portion 252-1 may be formed by an anisotropic deposition process so that the third thickness T3 is less than the fourth thickness T4. In some embodiments, the anisotropic deposition process for forming the barrier portion 252-1 may include a physical vapor deposition process.

With reference to FIG. 2, in some embodiments, the semiconductor device 200a may include a metal layer 261 and a metal layer 262. The metal layer 261 may be disposed on the conductive contact 251. The metal layer 261 may be electrically connected to the conductive contact 251. The metal layer 262 may be disposed on the conductive contact 252. The metal layer 262 may be electrically connected to the conductive contact 252. The metal layer 261 and the metal layer 262 may include a conductive material. The conductive material may include tungsten, copper, aluminum, tantalum, or other suitable materials.

In this embodiment, the dimension (e.g., area or volume) of the fuse doped region 222 may be greater than that of the resistance modification doped region 224. In some embodiments, the fuse doped region 222 may have a portion 222a disposed under or below a lower boundary 224s1 of the resistance modification doped region 224. In some embodiments, the fuse doped region 222 may exceed a lateral boundary 224s2 of the resistance modification doped region 224.

In a comparative semiconductor device, when the fuse medium is blown out under an operation current less than 4 mA, the resistance of the blown fuse is negatively proportional to a temperature, and such fuse (or blown fuse) may be referred to as a hopping type fuse. The hopping type fuse has a resistance with a higher deviation, which may cause a misjudgment of the determination of a read operation and/or a write operation. In this embodiment, the resistance modification doped region 224 may make the fuse medium 231 to be an ohmic type fuse when the fuse medium 231 is blown out under an operation current less than 4 mA (e.g., a current less than 1.2 mA). The resistance of an ohmic type fuse is positively proportional to a temperature and has a lower deviation. As a result, the misjudgment of the determination of a read operation and/or a write operation can be reduced.

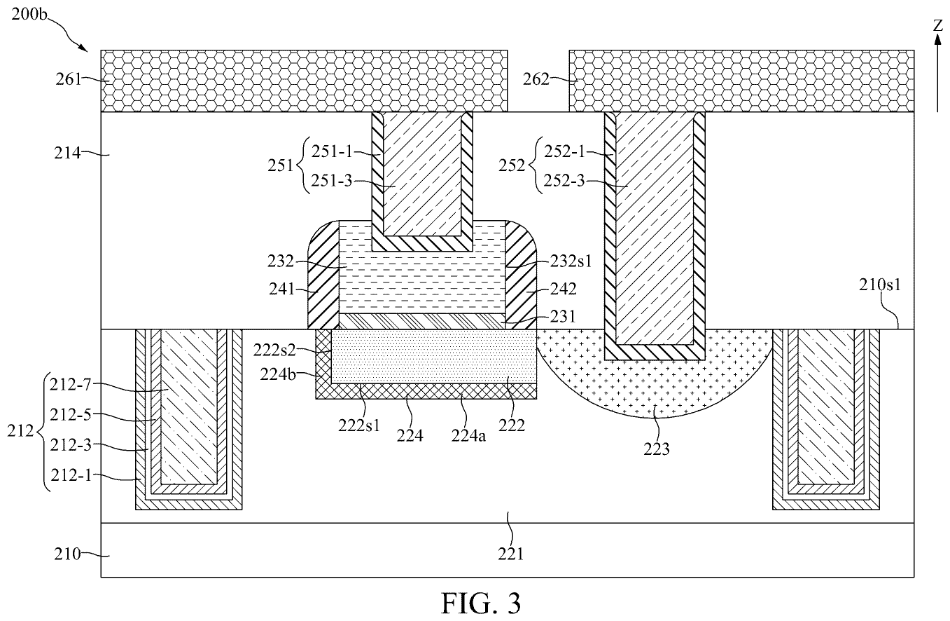

FIG. 3 is a cross-section of a semiconductor device 200b, in accordance with some embodiments of the present disclosure. The semiconductor device 200b is similar to the semiconductor device 200a as shown in FIG. 2, with differences therebetween as follows.

In some embodiments, the dimension (e.g., area or volume) of the fuse doped region 222 may be less than that of the resistance modification doped region 224. In some embodiments, the resistance modification doped region 224 may have a portion 224a disposed under or below a lower boundary 222s1 of the fuse doped region 222. In some embodiments, the resistance modification doped region 224 may exceed a lateral boundary 222s2 of the fuse doped region 222. In some embodiments, the resistance modification doped region 224b may be disposed between the fuse doped region 222 and the well region 221. In some embodiments, the spacer 241 may vertically overlap the resistance modification doped region 224. In some embodiments, the spacer 242 may vertically overlap the fuse doped region 222. In some embodiments, the fuse doped region 222 may be in contact with the S/D region 223. In some embodiments, the fuse doped region 222 may partially overlap the S/D region 223.

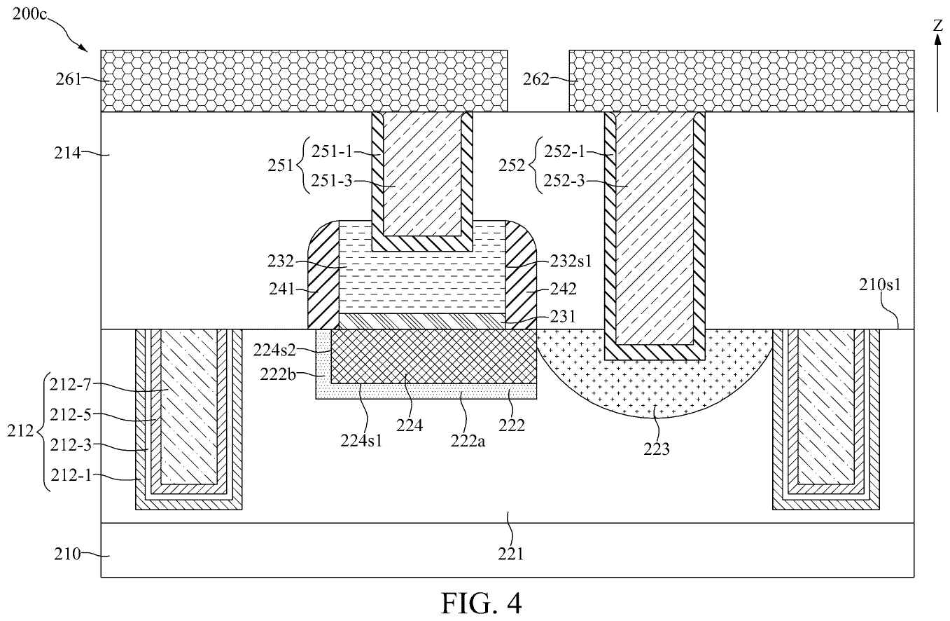

FIG. 4 is a cross-section of a semiconductor device 220c, in accordance with some embodiments of the present disclosure. The semiconductor device 200c is similar to the semiconductor device 200a as shown in FIG. 2, with differences therebetween as follows.

In some embodiments, the fuse doped region 222 may have a portion 222b exceeding the lateral boundary 224s2 of the resistance modification doped region 224. In some embodiments, the spacer 241 may be free from vertically overlapping the resistance modification doped region 224, and the spacer 242 may vertically overlap with the resistance modification doped region 224.

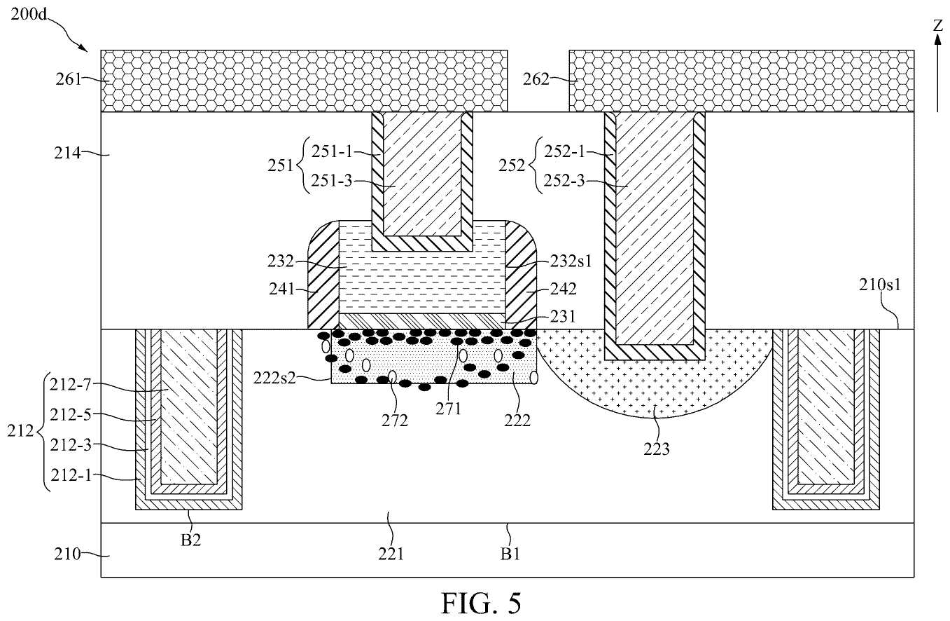

FIG. 5 is a cross-section of a semiconductor device 200d, in accordance with some embodiments of the present disclosure. The semiconductor device 200d is similar to the semiconductor device 200a as shown in FIG. 2, with differences therebetween as follows.

In some embodiments, the semiconductor device 200d may include impurities 271 and impurities 272. In some embodiments, the impurity 271 may be doped within the well region 221. In some embodiments, the impurity 271 may be doped under the gate electrode 232. In some embodiments, the impurity 271 may be doped within the fuse doped region 222. The impurity 271 may include nitrogen derivative impurities. In some embodiments, the impurity 271 may include nitride. In some embodiments, the impurity 271 may include oxynitride. In some embodiments, a portion of the impurity 271 may be located beyond or outside the fuse doped region 222. In some embodiments, the impurity 271 may be located under the spacer 241. In some embodiments, the impurity 271 may be located under the spacer 242. In some embodiments, the concentration of the impurity 271 may be gradient or uneven. For example, the impurity 271 may have a higher concentration near the surface 210s1 and a lower concentration below the fuse doped region 222.

In some embodiments, the impurity 272 may be doped within the well region 221. In some embodiments, the impurity 272 may be doped under the gate electrode 232. In some embodiments, the impurity 272 may be doped within the fuse doped region 222. The impurity 272 may include nitrogen.

The impurity 271 and/or 272 may modify the resistance of the fuse and make the fuse medium 231 to be an ohmic type fuse when the fuse medium 231 is blown out under an operation current under 4 mA (e.g., a current under 1.2 mA). As a result, the misjudgment of the determination of a read operation and/or a write operation can be reduced.

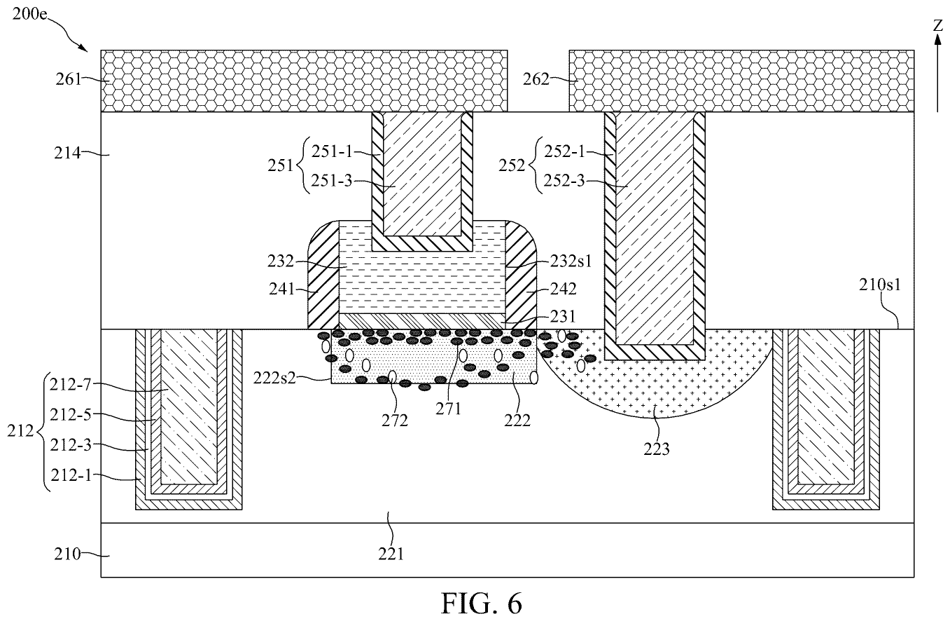

FIG. 6 is a cross-section of a semiconductor device 200e, in accordance with some embodiments of the present disclosure. The semiconductor device 200d is similar to the semiconductor device 200d as shown in FIG. 5, with differences therebetween as follows.

In some embodiments, the impurity 271 may be located within the S/D region 223. In some embodiments, the impurity 272 may be located within the S/D region 223.

FIGS. 7 to 22 illustrates one or more stages of an exemplary method for manufacturing a semiconductor device according to some embodiments of the present disclosure.

Referring to FIG. 7, a substrate 210 may be provided. The substrate 210 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenide, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

With reference to FIG. 7, the well region 221 is formed in the substrate 210. The well region 221 may be formed by an ion implantation process, and p-type dopants, such as boron, gallium, or indium, or n-type dopants, such as phosphorus or arsenic, can be implanted to form the well region 221, depending on the conductive type of the substrate 210. In some embodiments, the conductive type of the well region 221 may be opposite to the conductive type of the substrate 210. For example, in some embodiments, the well region 221 may be p-type, and the substrate 210 may be n-type.

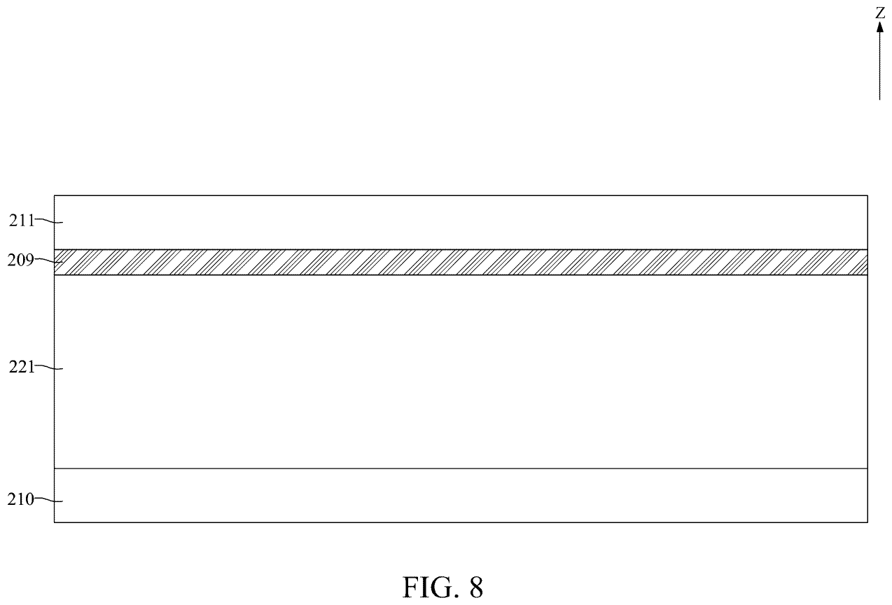

With reference to FIG. 8, a pad oxide layer 209 and a pad nitride layer 211 may be sequentially formed over the substrate 210 and covering the well region 221. In some embodiments, the pad oxide layer 209 may be formed of silicon oxide, and the pad nitride layer 211 may be formed of silicon nitride. The pad oxide layer 209 and the pad nitride layer 211 may be formed by thermal oxidation, chemical vapor deposition, atomic layer deposition and/or other applicable method.

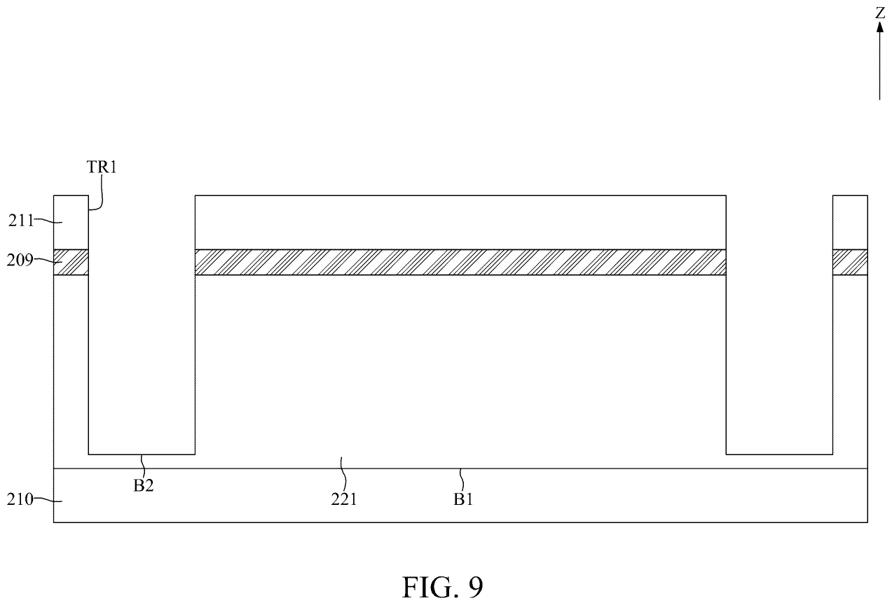

With reference to FIG. 9, after the pad nitride layer 211 is formed, a shallow trench TR1 may be formed penetrating through the pad nitride layer 211 and the pad oxide layer 209 and extending into the well region 221. In some embodiments, the bottom surface B2 of the shallow trench TR1 may be located in the well region 221 and higher than the bottom surface B1 of the well region 221. In some embodiments, the formation of the shallow trench TR1 may include forming a patterned mask (not shown) over the pad nitride layer 211 and etching the underlying structure by using the patterned mask as a mask. The etching may be performed using a wet etching process, a dry etching process, or a combination thereof. After the shallow trench TR1 is formed, the patterned mask may be removed using, for example, an ashing process followed by a wet clean process.

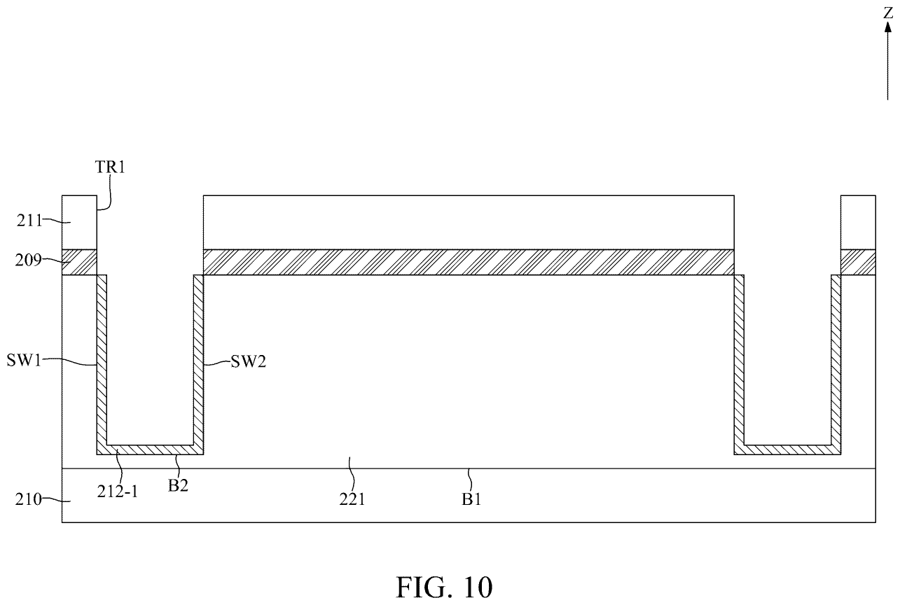

With reference to FIG. 10, a first liner 212-1 may be formed over the sidewalls and the bottom surface B2 of the shallow trench TR1. Detailedly, the exposed sidewalls SW1 and SW2 and the exposed surface of the well region 221 (i.e., the bottom surface B2 of the shallow trench TR1) may be covered by and in direct contact with the first liner 212-1.

In some embodiments, the first liner 212-1 may be formed of silicon oxide and may be formed by an oxidation process. In some embodiments, the oxidation process for forming the first liner 223 may be a selective oxidation due to different compositions of the well region 221, the pad oxide layer 209 and the pad nitride layer 211. In some embodiments, the exposed sidewalls and/or surfaces of the well region 221 may be completely covered by the first liner 223, while the sidewalls of the pad nitride layer 211 and the pad oxide layer 209 in the shallow trench TR1 may be at least partially exposed.

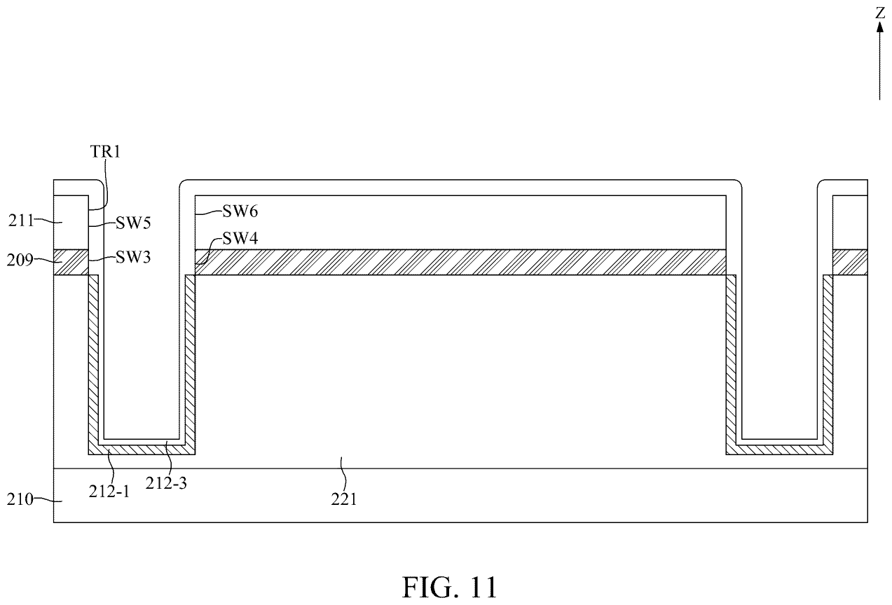

With reference to FIG. 11, a second liner 212-3 may be formed over the first liner 212-1. In some embodiments, the second liner 212-3 may be conformally formed over the top surface of the pad nitride layer 211 and lining the remaining portion of the shallow trench TR1. In some embodiments, the first liner 212-1 may be completely covered by the second liner 212-3, and the exposed sidewalls SW5 and SW6 of the pad nitride layer 211, the exposed sidewalls SW3 and SW4 of the pad oxide layer 209 may be covered by and in direct contact with the second liner 212-3. In some embodiments, the second liner 212-3 may be formed of nitride and may be formed by nitridation process, such as a rapid thermal nitridation (RTN) process.

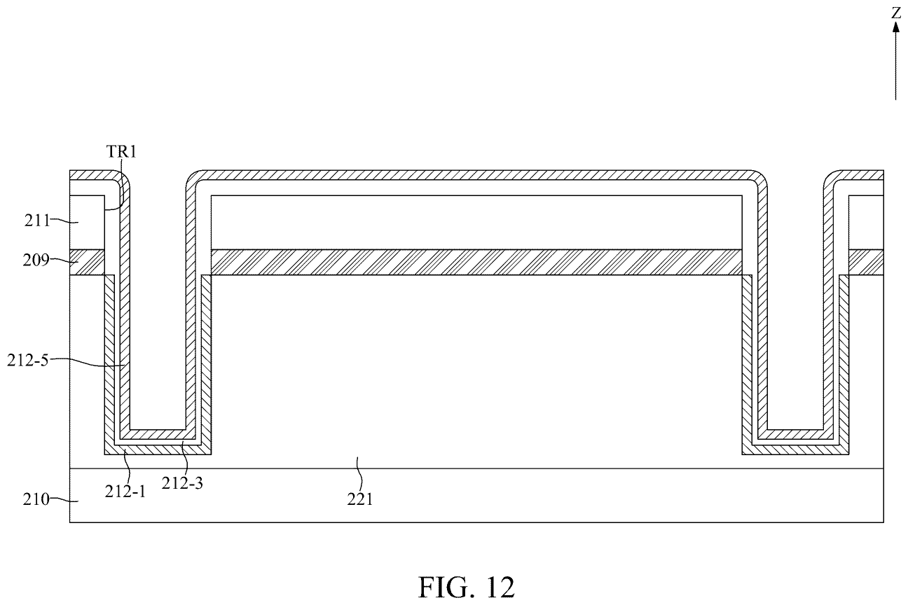

With reference to FIG. 12, a third liner 212-5 may be formed over the second liner 212-3. In some embodiments, the third liner 212-5 may be conformally formed over the top surface of the pad nitride layer 211 and lining the remaining portion of the shallow trench TR1. In some embodiments, the third liner 212-5 may be formed of silicon oxynitride and may be formed by an in-situ steam generation (ISSG) process.

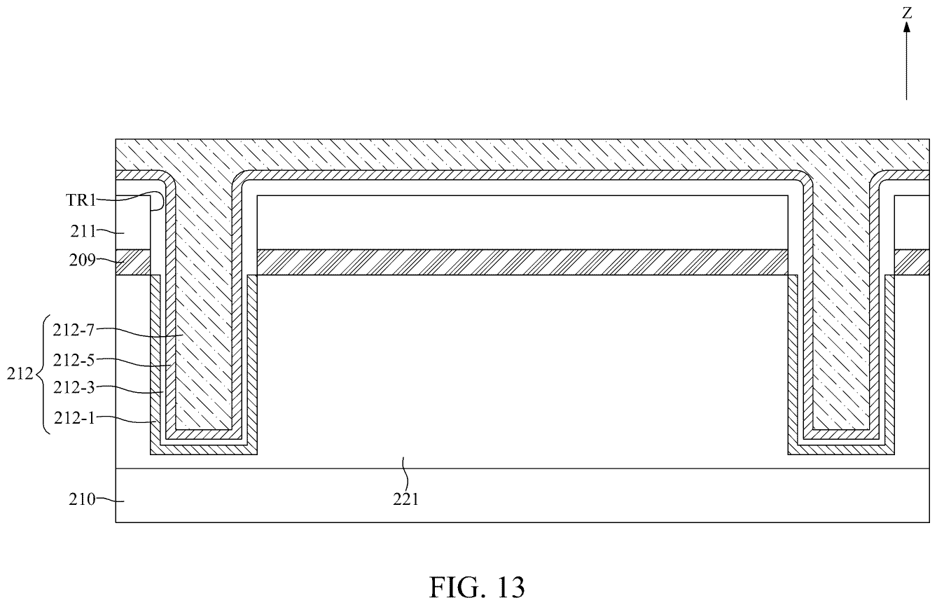

With reference to FIG. 13, a trench filling layer 212-7 may be formed over the third liner 212-5 and fill the remaining portion of the shallow trench TR1. In some embodiments, the trench filling layer 212-7 may be formed of a dielectric material, such as silicon oxide, silicon nitride, silicon oxynitride, silicon carbonitride, silicon oxide carbonitride, or a combination thereof. It should be noted that the material of the trench filling layer 212-7 is different from the materials of the second liner 212-3 and the third liner 212-5, such that sufficient etching selectivities exist between the second liner 212-3 and the trench filling layer 212-7 and between the third liner 212-5 and the trench filling layer 212-7. In some embodiments, the trench filling layer 212-7 may be formed by a deposition process, such as a chemical vapor deposition process or an atomic layer deposition process.

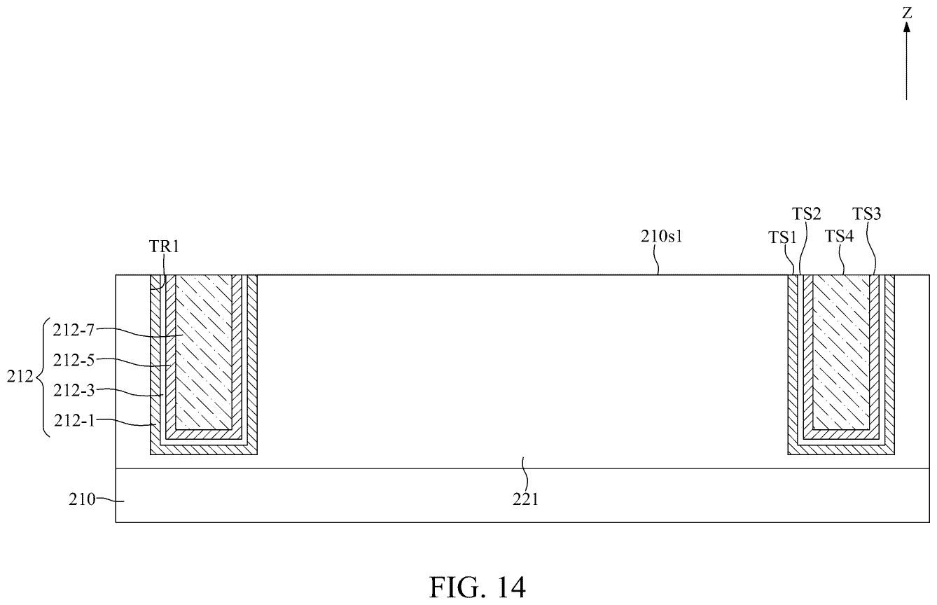

With reference to FIG. 14, a planarization process may be performed on the trench filling layer 212-7, the third liner 212-5, and the second liner 212-3 to expose the top surface 210s1 of the substrate 210, such that the top surfaces TS1, TS2, TS3, TS4 of the trench filling layer 212-7, the third liner 212-5, the second liner 212-3, and the first liner 212-1 may be substantially coplanar with each other. In some embodiments, the planarization process may be a chemical mechanical polishing process. After the planarization process, an isolation structure 212 may be formed within the well region 221 to define a region of a fuse.

Since there are multiple liners surrounding the trench filling layer 212-7, and etching selectivities exist between the liners 212-1, 212-3, 212-5 and the trench filling layer 212-7, the sidewalls of the well region 221 may be protected from being exposed during subsequent etching process. As a result, defects such as electrical shorts may be prevented.

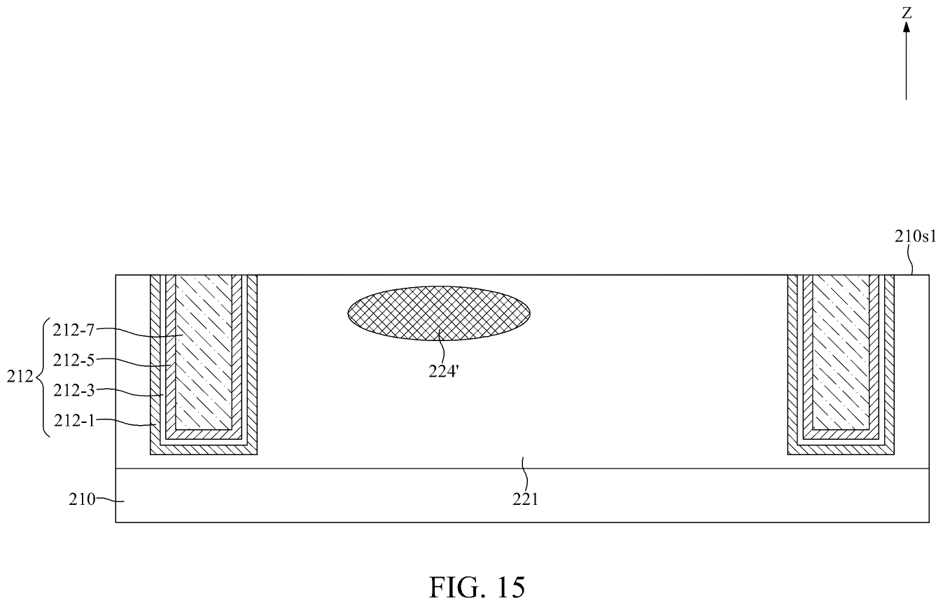

With reference to FIG. 15, a doped region 224′ may be doped into the well region 221. The doped region 224′ may be doped by an implantation technique. In some embodiments, the doped region 224′ may include nitrogen. In some embodiments, the ion implantation energy of the doped region 224′ may range from about 10 keV to about 30 keV, such as 10 keV, 15 keV, 20 keV, 25 keV, or 30 keV.

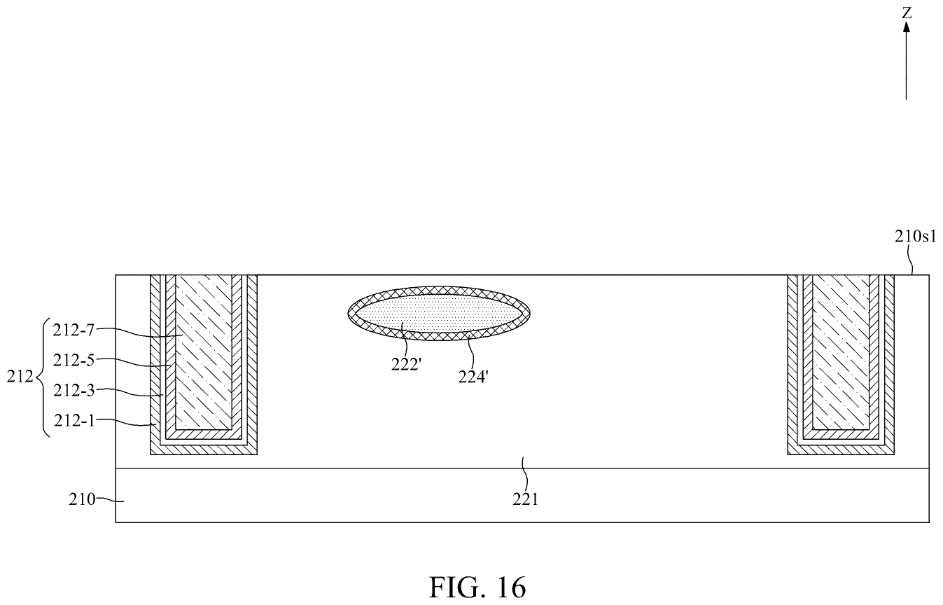

With reference to FIG. 16, a doped region 222′ may be doped into the well region 221. The doped region 222′ may be doped by an implantation technique. In some embodiments, the doped region 222′ may include phosphorus, arsenic, antimony, or a combination thereof. In some embodiments, the implantation energy of the doped region 222′ may be greater than that of the doped region 224′. In some embodiments, implantation energy of the doped region 222′ may range from about 20 keV to about 40 keV, such as 20 keV, 25 keV, 30 keV, 35 keV, or 40 keV. Although FIG. 16 illustrates that the doped region 224′ may be formed before the doped region 222′, the doped region 222′ may be formed before the doped region 224′ in other embodiments.

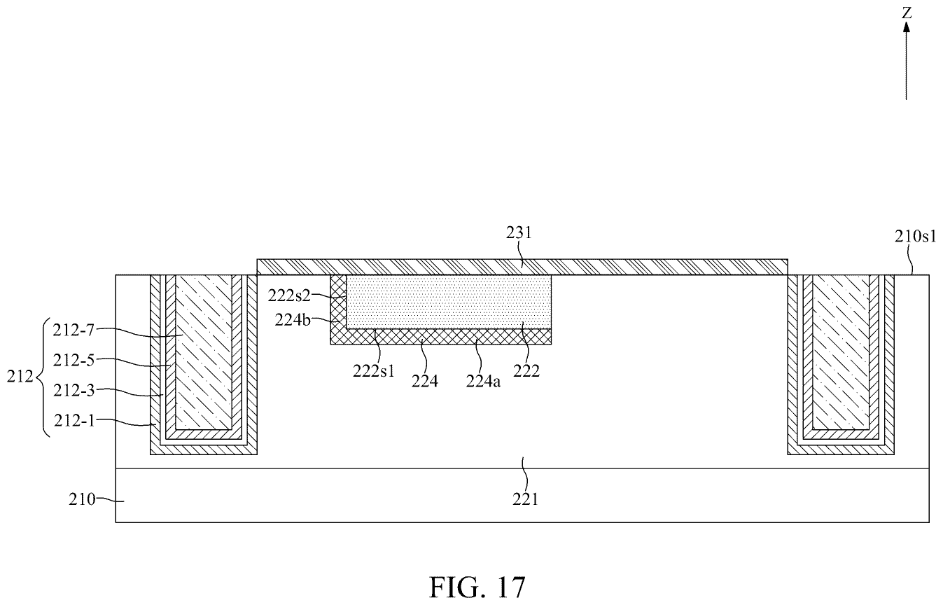

With reference to FIG. 17, a fuse medium 231 may be formed over the surface 210s1 of the substrate 210. In some embodiments, the doped region 222′ may be activated to form a fuse doped region 222. In some embodiments, the doped region 224′ may be activated to form a resistance modification doped region 224. In some embodiments, a fuse medium 231 may be formed by a thermal oxidation, and therefore the doped region 222′ and the doped region 224′ may be activated.

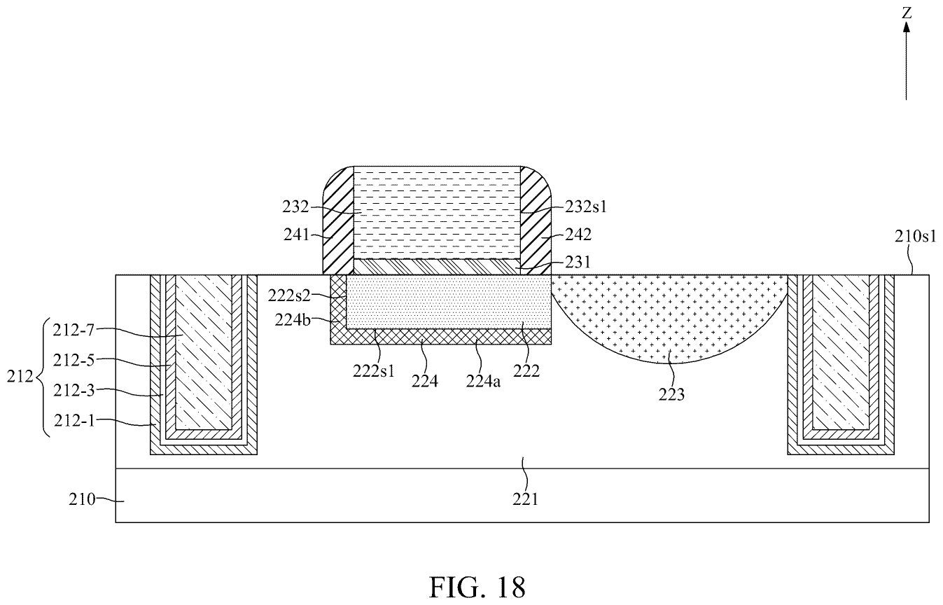

With reference to FIG. 18, the fuse medium 231 may be patterned. A gate electrode 232 may be formed over the fuse medium 231. Spacers 241 and 242 may be on opposite sides of the gate electrode 232. A S/D region 223 may be formed between the fuse doped region 222 and the isolation structure 212. The gate electrode 232, spacer 241, and/or spacer 242 may be formed by a deposition process, such as a chemical vapor deposition process, an atomic layer deposition process, a physical vapor deposition process, or a combination thereof. The S/D region 223 may be formed by an implantation technique.

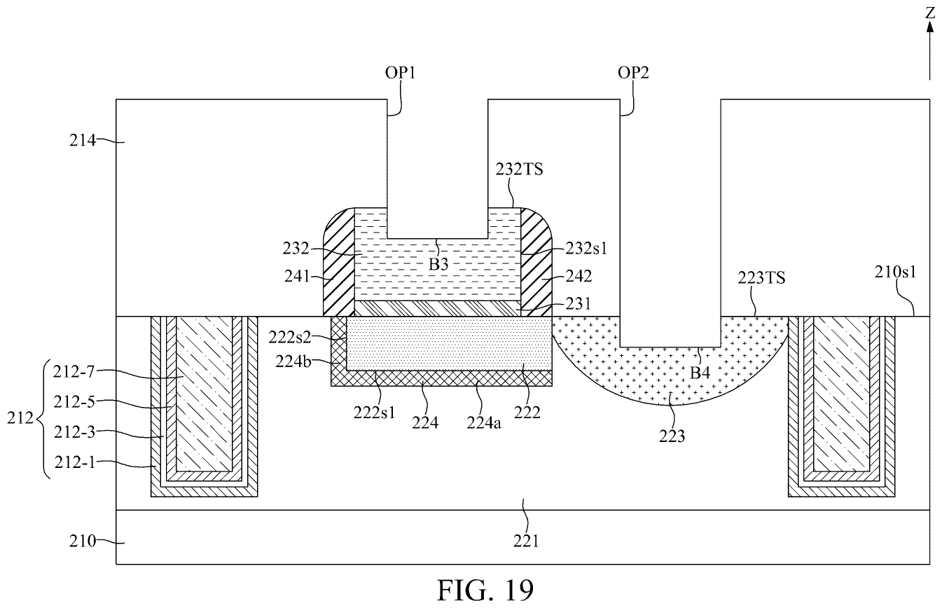

With reference to FIG. 19, a dielectric layer 214 may be formed over the well region 221 and cover the gate electrode 232, the spacer 241, the spacer 242, the S/D region 223, and the isolation structures 212. In some embodiments, the dielectric layer 214 may be formed of, for example, silicon oxide, undoped silicate glass, fluorosilicate glass, borophosphosilicate glass, a spin-on low-k dielectric layer, a chemical vapor deposition low-k dielectric layer, or a combination thereof. In some embodiments, the dielectric layer 214 may include a self-planarizing material such as a spin-on glass or a spin-on low-k dielectric material such as SiLK™. In some embodiments, the dielectric layer 214 may be formed by a deposition process including, for example, chemical vapor deposition, plasma enhanced chemical vapor deposition, evaporation, or spin-on coating. A planarization process, such as chemical mechanical polishing, may be performed to remove excess material and provide a substantially flat surface for subsequent processing steps.

With reference to FIG. 19, a first opening OP1 may be formed penetrating the dielectric layer 214 and extending to the gate electrode 232. The bottom surface B3 of the first opening OP1 may be lower than the top surface 232TS of the gate electrode 232. A second opening OP2 may be formed penetrating the dielectric layer 214 and extending to the S/D region 223. The bottom surface B4 of the second opening OP2 may be lower than the top surface 223TS of the S/D region 223.

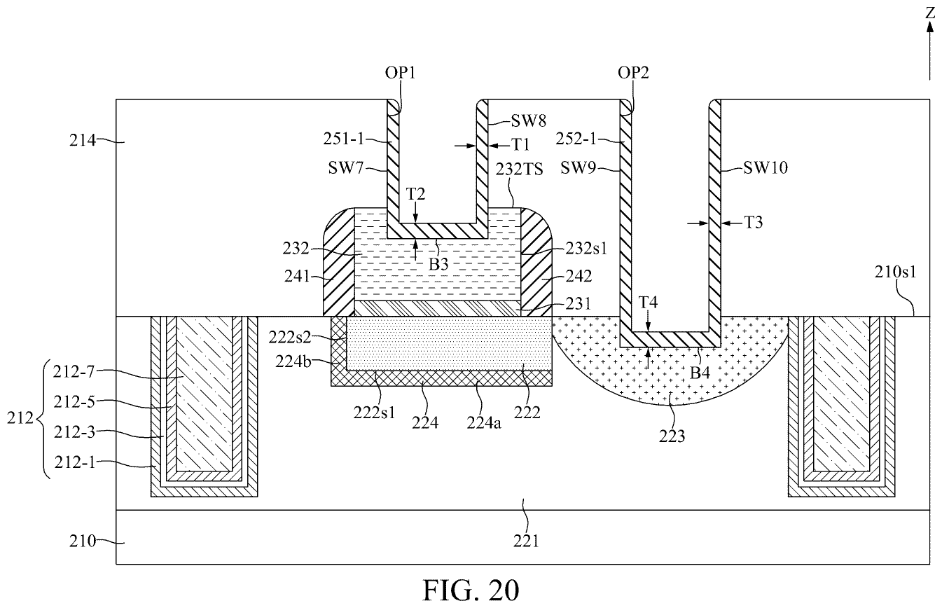

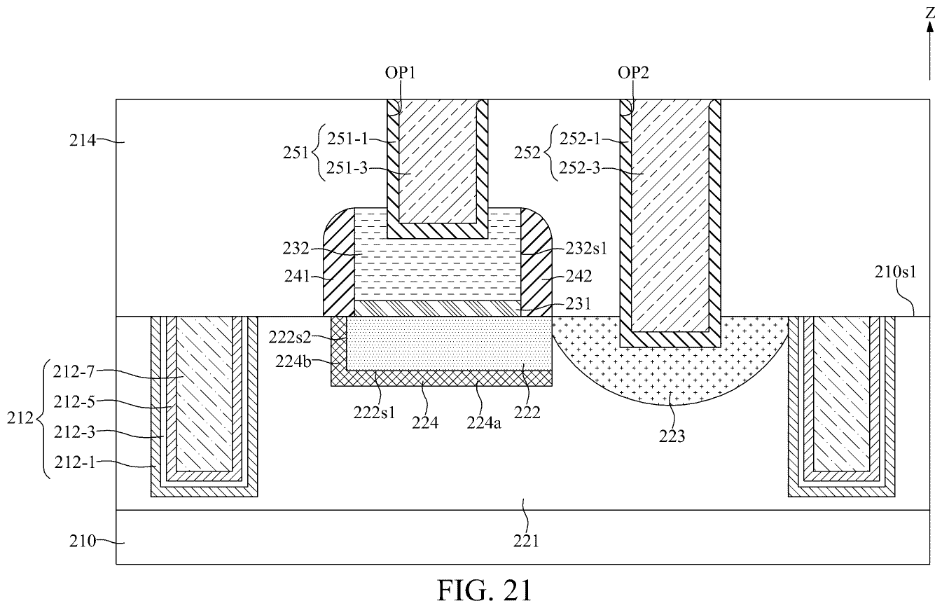

With reference to FIGS. 20 and 21, a conductive contact 251 may be formed over the gate electrode 232. The conductive contact 251 may include a barrier portion 251-1 and a bulk portion 251-3. A conductive contact 252 may be formed over the S/D region 223. The conductive contact 252 may include a barrier portion 252-1 and a bulk portion 252-3. Detailed process may be illustrated as follows.

With reference to FIG. 20, an anisotropic deposition process may be performed to form the barrier portion 251-1 of the conductive contact 251 and the barrier portion 252-1 of the conductive contact 252. The barrier portion 251-1 may cover the sidewalls SW7, SW8 and the bottom surface B3 of the first opening OP1. The barrier portion 252-1 may cover the sidewalls SW9, SW10 and the bottom surface B4 of the second opening OP2. In some embodiments, the barrier portions 251-1, 252-1 may include titanium, titanium nitride, or a combination thereof.

In some embodiments, the anisotropic deposition process may be performed so as to ensure that the first thicknesses T1 of the barrier portion 251-1 on the sidewalls SW7, SW8 of the first opening OP1 are less than the second thicknesses T2 of the barrier portion 251-1 on the bottom surface B3 (also referred to as the bottom surface 251BS of the conductive contact 251) of the first opening OP1, and the third thickness T3 of the barrier portion 252-1 on the sidewalls SW9, SW10 of the second opening OP2 are less than the fourth thicknesses T4 of the barrier portion 252-1 on the bottom surface B4 (also referred to as the bottom surface 252BS of the conductive contact 252) of the second opening OP2. In some embodiments, the anisotropic deposition process includes a physical vapor deposition process.

With reference to FIG. 21, the bulk portions 251-3, 252-3 may be formed in the remaining portions of the first opening OP1 and second opening OP2 over the barrier portions 251-1, 252-1 to form the conductive contact 251 and the conductive contact 252 respectively and correspondingly. In some embodiments, the bulk portions 251-3, 252-3 may include tungsten. In some embodiments, the bulk portions 251-3, 252-3 may be formed by a deposition process, and a subsequent planarization process.

Since the first thickness T1 of the barrier portion 251-1 is less than the second thickness T2 of the barrier portion 251-1 and the third thickness T3 of the barrier portion 252-1 is less than the fourth thickness T4 of the barrier portion 252-1, the barrier portions 251-1, 252-1 can be prevented from overhanging at the top corners of the first opening OP1 and the second opening OP2, which is beneficial for forming void-free bulk portions 251-3, 252-3. As a result, the device performance of the semiconductor device may be enhanced.

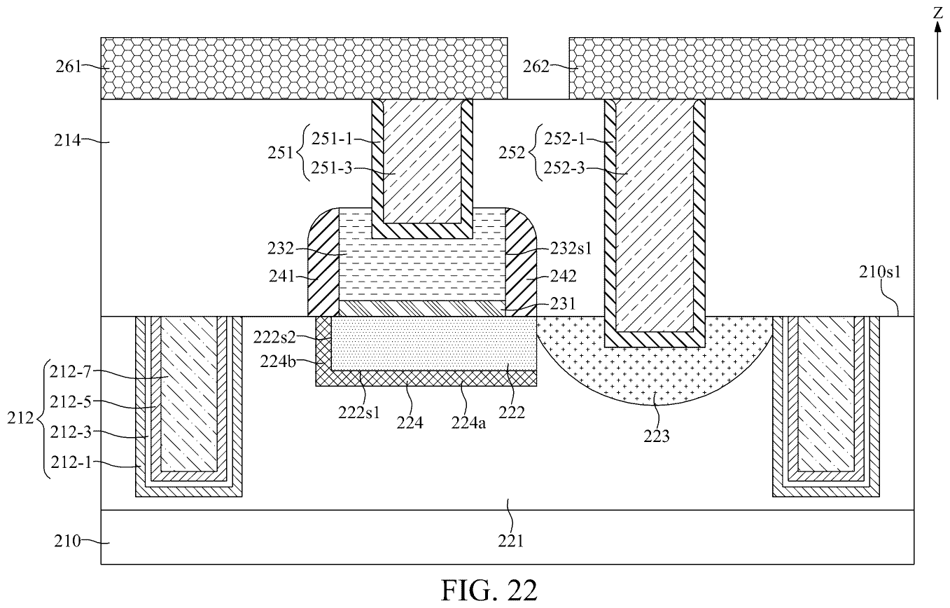

With reference to FIG. 22, a metal layer 261 may be formed over the conductive contact 251. A metal layer 262 may be formed over the conductive contact 252. The metal layer 261 and metal layer 262 may be formed by a deposition process, such as a chemical vapor deposition process, an atomic layer deposition process, a physical vapor deposition process, a sputtering process, a plating process, or a combination thereof.

FIG. 23 illustrates a diagram showing a relation between a temperature and a resistance of a hopping type fuse. The horizontal axis indicates a resistance. The vertical axis indicates a cumulative percentage of test results of comparative semiconductor devices. The solid line is a distribution of resistances of semiconductor devices under a higher temperature. The dotted line is a distribution of resistances of semiconductor devices under a lower temperature. The resistance is measured after a fuse medium is blown out under an operation current ranging from about 0.4 mA to about 1.2 mA. The operation voltage may range from about 4V to about 6V. The comparative semiconductor devices do not include a resistance modification doped region, such as the resistance modification doped region 224 as shown in FIG. 2. As shown in FIG. 23, the comparative semiconductor device has a lower resistance under a higher temperature and a higher resistance under a lower temperature. As shown in FIG. 23, the resistance of 90% of the measurement results range between about 3 kohm and about 15 kohm.

FIG. 24 illustrates a diagram showing a relation between a temperature and a resistance of an ohmic type fuse. The horizontal axis indicates a resistance. The vertical axis indicates a cumulative percentage of test results of comparative semiconductor devices. The solid line is a distribution of resistances of semiconductor devices under a higher temperature. The dotted line is a distribution of resistances of semiconductor devices under a lower temperature. The resistance is measured after a fuse medium is blown out under an operation current ranging from about 0.4 mA to about 1.2 mA. The operation voltage may range from about 4V to about 6V. The comparative semiconductor devices include a resistance modification doped region, such as the resistance modification doped region 224 as shown in FIG. 2. The dopant concentration of the resistance modification doped region 224 is about 3E15 atoms/cm³. As shown in FIG. 24, the semiconductor device has a lower resistance under a lower temperature and a higher resistance under a higher temperature. As shown in FIG. 24, the resistance of 90% of the measurement results range between about 1 kohm and about 4 kohm. Therefore, in comparison with FIG. 23, the deviation of the resistance of FIG. 24 is smaller.

FIG. 25 illustrates a diagram showing a relation between a temperature and a resistance of an ohmic type fuse. The horizontal axis indicates a resistance. The vertical axis indicates a cumulative percentage of test results of comparative semiconductor devices. The solid line is a distribution of resistances of semiconductor devices under a higher temperature. The dotted line is a distribution of resistances of semiconductor devices under a lower temperature. The resistance is measured after a fuse medium is blown out under an operation current ranging from about 0.4 mA to about 1.2 mA. The operation voltage may range from about 4V to about 6V. The comparative semiconductor devices include a resistance modification doped region, such as the resistance modification doped region 224 as shown in FIG. 2. The dopant concentration of the resistance modification doped region 224 is about 5E15 atoms/cm³. As shown in FIG. 25, the semiconductor device has a lower resistance under a lower temperature and a higher resistance under a higher temperature. As shown in FIG. 25, the resistance of 90% of the measurement results range between about 1 kohm and about 3.7 kohm. Therefore, in comparison with FIG. 23, the deviation of the resistance of FIG. 25 is smaller.

FIG. 26 is a flowchart illustrating a method 300 of manufacturing a semiconductor device, in accordance with some embodiments of the present disclosure.

The method 300 may begin with operation S11 in which a substrate may be provided, a well region may be formed in the substrate, and a plurality of isolation structures 212 may be formed in the well region.

The method 300 may begin with operation S13 in which a fuse doped region may be formed within the well region. The fuse doped region may have a conductive type different from the conductive type of the well region.

The method 300 may begin with operation S15 in which a resistance modification doped region may be formed within the well region. The resistance modification doped region may have a conductive type different from the conductive type of the well region. The resistance modification doped region may partially overlap the fuse doped region.

The method 300 may begin with operation S17 in which the resistance modification doped region and the fuse doped region may be activated. A fuse medium may be formed over the fuse doped region and over the resistance modification doped region.

The method 300 may begin with operation S19 in which a gate electrode may be formed over the fuse medium to cover the fuse doped region and the resistance modification doped region. An S/D region may be formed adjacent to the fuse doped region and within the substrate.

The method 300 may begin with operation S21 in which conductive contacts and metal layers may be formed. As a result, a semiconductor device may be produced.

The method 300 is merely an illustrative example and is not intended to limit the present disclosure beyond what is explicitly recited in the claims. Additional operations can be provided before, during, or after each operation of the method 300, and some operations described can be replaced, eliminated, or reordered for additional embodiments of the method. In some embodiments, the method 300 can include further operations not depicted in FIG. 26. In some embodiments, the method 300 can include one or more operations depicted in FIG. 26.

One aspect of the present disclosure provides a semiconductor device including a substrate; a well region positioned within the substrate; an isolation structure positioned in the well region; a fuse medium positioned over the well region; a gate electrode positioned over the fuse medium; a fuse doped region positioned under the fuse medium and within the well region; a source/drain region positioned adjacent to the fuse doped region; and a resistance modification doped region partially overlapping the fuse doped region. The fuse doped region and the resistance modification doped region have a first conductive type and the well region has a second conductive type different from the first conductive type.

Another aspect of the present disclosure provides a semiconductor device including a substrate; a well region positioned within the substrate; an isolation structure positioned in the well region; a fuse medium positioned over the well region; a gate electrode positioned over the fuse medium; a fuse doped region positioned under the fuse medium and within the well region; a source/drain region positioned adjacent to the fuse doped region; and a plurality of impurities positioned within the well region and under the gate electrode. The fuse doped region has a first conductive type and the well region has a second conductive type different from the first conductive type.

Another aspect of the present disclosure provides a method for fabricating a semiconductor device including providing substrate; forming a well region in the substrate; forming an isolation structure in the well region; forming a resistance modification doped region within the well region; forming a fuse doped region within the well region; and forming a gate electrode over the fuse doped region. The fuse doped region and the resistance modification doped region have a first conductive type and the well region has a second conductive type different from the first conductive type.

Due to the design of the semiconductor device of the present disclosure, the resistance modification doped region 224 may make a fuse to be an ohmic type fuse when a fuse medium 231 is blown out under an operation current under 4 mA (e.g., a current under 1.2 mA). The resistance of an ohmic type fuse is positively proportional to a temperature and has a resistance with a lower deviation. As a result, the misjudgment of the determination of a read operation and/or a write operation can be reduced.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate;
a well region positioned within the substrate;
an isolation structure positioned in the well region;
a fuse medium positioned over the well region;
a gate electrode positioned over the fuse medium;
a fuse doped region positioned under the fuse medium and within the well region;
a source/drain region positioned adjacent to the fuse doped region; and
a resistance modification doped region partially overlapping the fuse doped region;
wherein the fuse doped region and the resistance modification doped region have a first conductive type and the well region has a second conductive type different from the first conductive type.

2. The semiconductor device of claim 1, wherein the isolation structure comprises:
a first liner inwardly positioned in the well region and comprising a U-shaped cross-sectional profile;
a second liner conformally positioned on the first liner and in the well region;
a third liner conformally positioned on the second liner and in the well region; and
a trench filling layer positioned in the well region and separated from the second liner by the third liner.

3. The semiconductor device of claim 2, wherein the first liner completely separates the second liner from the well region.

4. The semiconductor device of claim 2, wherein top surfaces of the trench filling layer, the third liner, the second liner, and the first liner are substantially coplanar.

5. The semiconductor device of claim 2, wherein the first liner comprises silicon oxide, the second liner comprises nitride, and the third liner comprises silicon oxynitride.

6. The semiconductor device of claim 2, wherein a bottom surface of the isolation structure is higher than a bottom surface of the well region.

7. The semiconductor device of claim 2, wherein the fuse doped region is in contact with the source/drain region.

8. The semiconductor device of claim 2, wherein the resistance modification doped region is in contact with the source/drain region.

9. The semiconductor device of claim 2, wherein a portion of the fuse doped region is located below the resistance modification doped region.

10. The semiconductor device of claim 2, wherein a portion of the resistance modification doped region is located below the fuse doped region.

11. The semiconductor device of claim 2, wherein a dopant concentration of the resistance modification doped region ranges from about 10¹⁵ atoms/cm³ to about 10¹⁶ atoms/cm³.

12. The semiconductor device of claim 2, wherein the fuse doped region comprises n-type dopants.

13. The semiconductor device of claim 2, wherein the resistance modification doped region comprises nitrogen.

14. The semiconductor device of claim 2, further comprising impurities within the well region and under the gate electrode.

15. The semiconductor device of claim 14, wherein the impurities comprise nitride and oxynitride.

16. The semiconductor device of claim 2, wherein the fuse medium is configured to be blown under a current ranging from about 0.4 mA to about 1.2 mA.

17. The semiconductor device of claim 2, wherein a resistance of the fuse medium is positively proportional to a temperature.

18. The semiconductor device of claim 2, further comprising a conductive contact positioned on and extending to the gate electrode.

19. The semiconductor device of claim 18, wherein the conductive contact comprises a barrier portion and a bulk portion, the barrier portion comprises a U-shaped cross-sectional profile and positioned on and extending to the gate electrode, and the bulk portion positioned on the barrier portion and surrounded by the barrier portion.

20. The semiconductor device of claim 19, wherein a thickness of the barrier portion under a bottom surface of the bulk portion is greater than a thickness of the barrier portion on sidewalls of the bulk portion.
